(19) United States
(12) Patent Application Publication
(10) Pub. No.: US 2025/0357144 A1
(43) Pub. Date: Nov. 20, 2025

(54) SEMICONDUCTOR STRUCTURE WITH THERMAL DISSIPATION LAYER AND METHOD OF MANUFACTURING THEREOF

(71) Applicant: Taiwan Semiconductor Manufacturing Company, Ltd., Hsin-Chu (TW)

(72) Inventors: Sam Vaziri, San Jose, CA (US); Xinyu Bao, Fremont, CA (US); Isha Datye, Hsinchu (TW)

(21) Appl. No.: 19/285,812

(22) Filed: Jul. 30, 2025

Related U.S. Application Data
(63) Continuation of application No. 18/609,682, filed on Mar. 19, 2024.
(60) Provisional application No. 63/596,356, filed on Nov. 6, 2023.

(51) Int. Cl. H01L 21/48; H01L 23/373; H01L 25/00; H01L 25/065

(52) U.S. Cl. CPC H01L 21/4807; H01L 23/3731; H01L 23/3732; H01L 25/0657; H01L 25/50; H01L 2225/06548; H01L 2225/06589

(57) ABSTRACT

One aspect of the present disclosure pertains to a method of semiconductor device fabrication. The method includes forming a transistor on a semiconductor substrate, forming a first metal layer and an overlying second metal layer over the transistor, depositing a thermal dissipation layer over the overlying second metal layer, and annealing the thermal dissipation layer to a temperature above the threshold temperature. The depositing of the thermal dissipation layer is performed below a threshold temperature. During the annealing, the first metal layer and the overlying second metal layer are maintained below the threshold temperature.

### PRIORITY DATA

This is a continuation application of U.S. patent application Ser. No. 18/609,682, filed Mar. 19, 2024, which claims benefit of U.S. Provisional Patent Application No. 63/596,356, filed Nov. 6, 2023, each of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology progresses, the concerns regarding thermal dissipation of heat generated by semiconductor devices, such as transistors, increase as higher temperatures may degrade device performance. The situation is further complicated in semiconductor devices that include multi-die configurations, such as a stacked die configuration, which further limit thermal dissipation paths. Therefore, although existing semiconductor device structures have generally been adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIGS. 1A, 1B, 1C, 1D, 1E, 1F, and 1G illustrate cross-sectional views of a semiconductor device structure at different manufacturing stages of forming a thermal dissipation layer thereon, according to some aspects of the present disclosure.

FIGS. 2A, 2B, 2C, and 2D illustrate diagrams of temperature, grain size, crystallization ratio, and crystal orientation consistency, respectively, versus a height of a thermal dissipation layer over a semiconductor device structure, according to some aspects of the present disclosure.

FIG. 3 illustrates a flow chart of an embodiment of a method of fabricating a semiconductor device having a thermal dissipation layer, according to aspects of the present disclosure.

FIGS. 4, 5, 6, 7, 8, 9, 10, and 11 are cross-sectional views of a semiconductor structure according to interim fabrication steps corresponding the method of FIG. 3, according to some aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor structures, such as integrated circuit (IC) structures comprising one or more dies to form the semiconductor structure. These structures may be referred to as 3D ICs as they integrate ICs in a vertical direction in part by stacking dies. The components of the stacked structure may be connected physically and/or through electrical connections. 3D ICs provide for form factor advantages and power and performance advantages including due to the interconnect lengths between the stacked devices. One application of a 3D IC structure is a processor and one or more memory chips vertically stacked. However, the semiconductor structures, including 3D ICs, can experience challenges with thermal dissipation from within the structure.

Thus, some of the embodiments presented herein provide for semiconductor structures to include thermal dissipation layers, also referred to as heat spreading layers, to provide for thermal dissipation paths. In some implementations, a thermal conductive material is implemented as a thermal dissipation layer to provide a high thermal conductivity in a 3D IC. In the context of the present disclosure, the terms “conductive” and “conductivity” specifically refer to “electrically conductive” and “electrical conductivity,” respectively, to distinguish from the terms “thermal conductive” and “thermal conductivity.” A thermal conductive material, as used herein, is defined as a material with a thermal conductivity of not less than 10 W/m-K (Watts per meter-Kelvin). In some embodiments, the thermal conductive material may include boron nitride (BN) (such as hexagonal-BN (h-BN) or cubic-BN (c-BN)), aluminum nitride (AlN), graphene, carbon, diamond, diamond-like carbon, benzoic acid (BA), transition metal dichalcogenides (TMDs) (e.g., MoS₂, MoSe₂, WS₂ or WSe₂), or the like. Thus, the present disclosure provides benefits for structures and methods that allow for high thermal conductivity between layers of the semiconductor structure (e.g., between dies) for thermal management.

In the following description, front-end-of-the-line (FEOL) generally refers to portions of the circuit where functional devices such as logic and memory devices are formed. The FEOL features include the transistors and features thereof such as source/drain features, channel regions, gate structures. Device-level contacts or metal features extend to the terminals of the transistor. Back-end-of-the-line (BEOL) in the present disclosure generally refers to components formed after the FEOL features and include a multi-layer interconnects (MLI). The MLI provide for a plurality of metal lines (also referred to as interconnect lines) and interposing vias that provide electrical connections including to the FEOL features. The metal lines provide for horizontal routing and the vias provide for a vertical routing to connect metal lines at different metal layers. Any number of metal layers may be used including for example, exemplary MLI may include five (5) or more metal lines vertically stacked typically referred to as M1, M2, M3, M4, M5, and so forth. The MLI includes dielectric or insulating materials that surround the metal lines and vias to provide for suitable structural support. The dielectric or insulating materials can be referred to as an inter-metal dielectric (IMD) as discussed below.

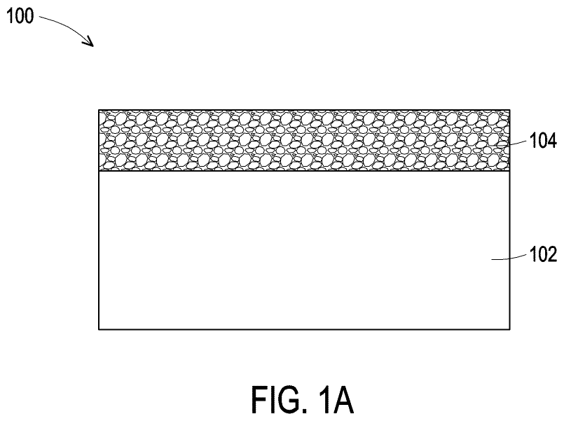

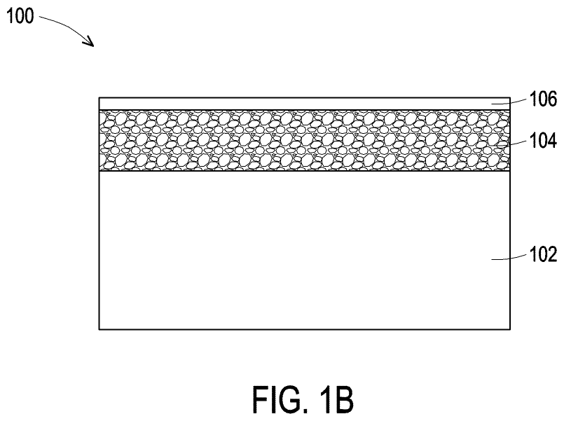

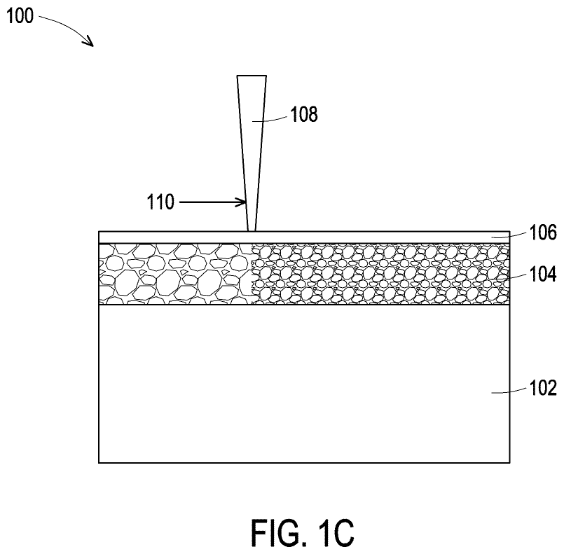

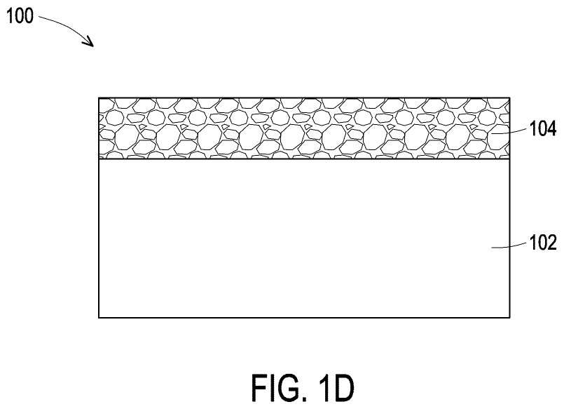

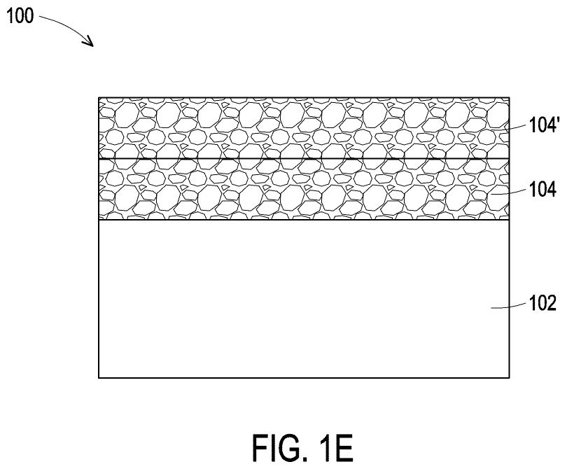

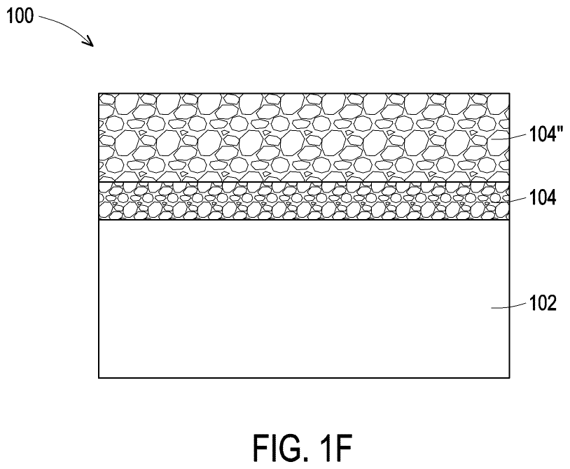

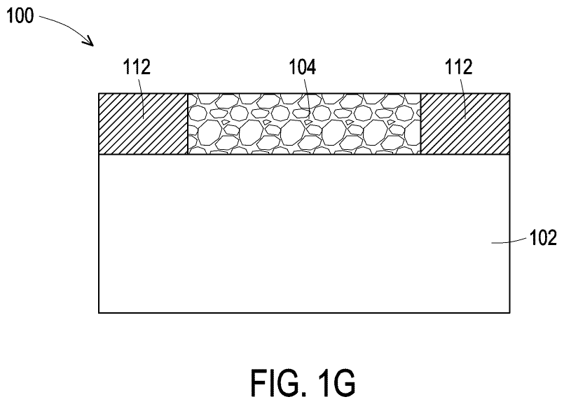

FIG. 1A illustrates a cross-sectional view of a portion of a semiconductor structure 100, according to an embodiment of the present disclosure. The semiconductor structure 100 may be a portion of an integrated circuit (IC) device and may include a plurality of device features (not shown).

As will be described further below with respect to various embodiments, the semiconductor structure 100 is formed on a semiconductor structure that has undergone FEOL processes. Such FEOL processes may form various transistors on the substrate to serve different functions. For example, these various transistors may form a central processing unit (CPU), a graphics process unit (GPU), access transistors for memory devices, image signal processing (ISP) circuitry, and/or other suitable circuitry. The transistors may be planar transistors or multi-gate transistors. A planar device refers to a device having a gate structure that engages a planar surface of a semiconductor active region. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, or other nanostructures and for that reason, a GAA transistor may also be referred to as a nanowire transistor or a nanosheet transistor. The transistors are referred to herein generally, and each of the configurations discussed applies to the embodiments herein.

The semiconductor structure 100 includes a multi-layer interconnect (MLI) structure that includes multiple metal layers and is part of the BEOL as discussed above. One metal layer 102 of the MLI is illustrated. In some implementations, the metal layer 102 is a top or uppermost metal layer of the ML. In some implementations, the metal layer 102 is a middle metal layer of the MLI, such as a metal layer at or above M3 but under the uppermost metal layer of the ML. In some embodiments, the semiconductor structure 100 is formed on a semiconductor substrate that includes silicon (Si). Alternatively or additionally, substrate includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate includes one or more group III-V materials, one or more group II-IV materials, or combinations thereof. In some implementations, the substrate is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods.

The MLI of the semiconductor structure 100 includes a plurality of metal lines or layers in the MLI, for example, an MLI may typically include about five (5) to about twenty (20) metal layers (or metallization layers). Each of the metal layers of the MLI include multiple vias and metal lines embedded in a dielectric or insulating layer, which may also be referred to herein as an intermetal dielectric (IMD) layer. The vias and metal lines may be formed of titanium (Ti), ruthenium (Ru), nickel (Ni), cobalt (Co), copper (Cu), molybdenum (Mo), tungsten (W), or aluminum (Al). In an embodiment, they are formed of copper (Cu). The IMD layer may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the IMD layer includes silicon oxide.

Illustrated in FIG. 1A is a metal layer 102. In an embodiment, the metallization layer 102 is an uppermost metal layer of an MLI of the semiconductor structure 100. In an embodiment, the metal layer 102 is an uppermost metal layer of a die of the semiconductor structure 100 (e.g., a bottom die). In an embodiment, the metal layer 102 is a middle metal layer of the MLI of the semiconductor structure 100, such as a metal layer at or above M4 but under the uppermost metal layer of the MLI. The metal layer 102 may include metal lines and/or vias formed of copper (Cu), titanium (Ti), ruthenium (Ru), nickel (Ni), cobalt (Co), copper (Cu), molybdenum (Mo), tungsten (W), aluminum (Al), or combinations thereof. The metal layer 102 includes IMD that surrounds the metal lines and/or vias. The IMD may be formed of silicon oxycarbide, silicon oxide, amorphous boron nitride (a-BN), SiCOH, SiCNH, PSG, BSG, BPSG, FSG, TEOS oxide, HSQ, MSQ, or the like. The IMD may also be a low-k (LK) dielectric layer having a dielectric constant value lower than about 3.9 or an extreme low-k (ELK) dielectric layer having a dielectric constant value lower than about 3.0.

In the semiconductor structure 100, on the metal layer 102 is a thermal dissipation layer 104. The thermal dissipation layer 104 is made of a thermal conductive material, such as boron nitride (BN), aluminum nitride (AlN), graphene, carbon, diamond, diamond-like carbon, benzoic acid (BA), transition metal dichalcogenides (TMDs) (e.g., MoS₂, MoSe₂, WS₂ or WSe₂), or the like. The thermal dissipation layer 104 may have a thickness of between approximately 0.1 microns (μm) and 10 μm. The thermal dissipation layer 104 may be deposited at a temperature less than or equal to approximately 400 degrees Celsius. Exemplary deposition methods include chemical vapor deposition (CVD), physical vapor deposition (PVD), and atomic layer deposition ALD. The temperature during deposition process being less than or equal to approximately 400 degrees Celsius is not trivial or arbitrary. This is because if the temperature exceeds 400 degrees Celsius, the high temperature may damage the BEOL features, particularly the dielectric material used in the IMD of the ML. Yet, thermal conductive material generally requires being deposited in a high temperature environment typically exceeding 400 degrees Celsius for ensuring crystal quality and thus achieving a high thermal conductivity. A low temperature deposition process may generally lead to a resulting thermal dissipation layer suffering from low crystal quality and thus low thermal conductivity. As to be discussed in further details below, the present disclosure further applies a post-deposition thermal treatment for implementing a local annealing process to the thermal dissipation layer 104. The annealing process is “local” as the high temperature region exceeding 400 degrees Celsius is constrained within the thermal dissipation layer 104 without causing the temperature in the underneath MLI to rise above 400 degrees Celsius.

FIG. 1B illustrates the semiconductor structure 100 having a capping layer 106 deposited on the thermal dissipation layer 104. The capping layer 106 may be composed of materials such as Ti, Al, Ni, silicon glass, Cr, Al₂O₃, SiO₂, carbon, or metal. The thermal dissipation layer 104 may have a thickness of between approximately 0.01 microns (μm) and 1 μm. The capping layer 106 serves two primary functions. Firstly, it acts as a light absorption layer, increasing the rate of light absorption when a pulsed laser is used in the post-deposition thermal treatment. Secondly, it serves as a thin protective layer that prevents the oxidation of the thermal dissipation layer 104 during the post-deposition thermal treatment. In some other embodiments, the deposition of the capping layer 106 may be skipped, such that the post-deposition thermal treatment may be directly applied to the thermal dissipation layer 104 without through the capping layer 106.

FIG. 1C illustrates the semiconductor structure 100 receiving the post-deposition thermal treatment. In the illustrated embodiment, a pulsed laser 108 is applied to deliver transient heat to the semiconductor structure 100. Such a transient heat treatment is also referred to as a post-deposition laser annealing process. In one embodiment, the pulsed laser 108 is applied in a scan mode. In one example, the pulsed laser 108 is scanned to the semiconductor structure 100 through an exemplary path 110. In the laser scan path, the laser beam scans through the semiconductor structure 100 line by line in parallel. The laser beam has an energy density unevenly distributed, such as a Gaussian distribution. The adjacent scan lines have a certain overlap to heat up the thermal dissipation layer 104 more evenly. In one embodiment, the laser source for the laser annealing process includes a pulsed solid state laser source. For example, the pulsed solid state laser source may have a short wavelength of about 355 nm, 405 nm, 532 nm, 633 nm, or other suitable wavelength. The input power density may be in the range of about 10 W/m to about 500 W/m for ultraviolet and visible wavelengths and may go up to 10,000 W/m for microwave range depending on the wavelength, repetition range, material and structure. The laser source may have a pulse rate between about 10 kHz and about 300 kHz. The laser pulse may have a duration between about 10 ns and about 10 us and a scanning rate between about 1 cm/s and about 10 cm/s. During the post-deposition laser annealing process, the semiconductor structure 100 may be in a vacuum environment or in an inert gas environment such as in Argon or Nitrogen. In some other embodiments, the semiconductor structure 100 may be an environment filled with air or H₂. The semiconductor structure 100 may be positioned on a temperature-controllable holder or a stage with a stage temperature set between about −60 degrees Celsius and about 375 degrees Celsius.

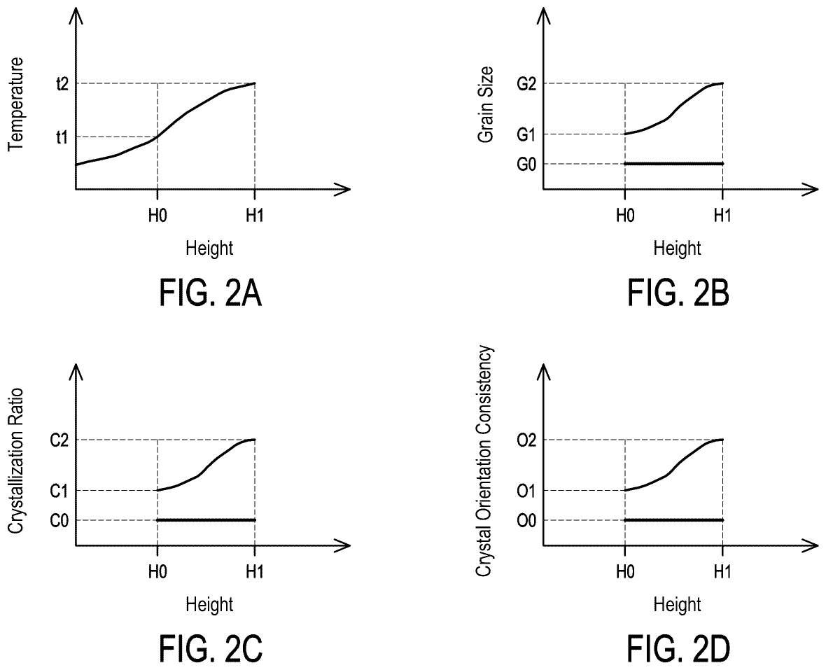

FIG. 2A illustrates the temperature gradient inside the semiconductor structure 100. The height H0 marks the top surface of the metal layer 102, and the height H1 marks the top surface of the thermal dissipation layer 104. That is, the thermal dissipation layer 104 expands between the markers H0 and H1. The temperature t1 at the interface between the metal layer 102 and the thermal dissipation layer 104 is controlled around 400 degrees Celsius, such that the temperature inside the metal layer 102 is well maintained below 400 degrees Celsius while temperature inside the thermal dissipation layer 104 is generally above the 400 degrees Celsius. The temperate t2 at the top surface of the thermal dissipation layer 104 may reach above 800 degrees Celsius in some embodiments.

The transient heat treatment improves the thermal conductivity of the thermal dissipation layer 104. In one aspect, the transient treatment improves the thermal conductivity by improving the thermal coupling at the grain boundaries and/or by treatment of dangling bonds and defects. In another aspect, the transient heat treatment improves the thermal conductivity by inducing melting or amorphous to crystalline transition or phase change in the thin film material. In one example, the thermal conductive material deposited during the low-temperature deposition process is boron nitride in amorphous form (a-BN), and converted to hexagonal from (h-BN), cubic form (c-BN), or a combination of hexagonal and cubic forms, which possesses a much higher thermal conductivity. In yet another aspect, the transient heat treatment improves the thermal conductivity by improving crystallinity and orientation alignment. In furtherance, the top surface of the semiconductor structure 100 may be pre-patterned prior to the deposition of the thermal conductive material to induce preferential crystal orientation during the transient laser heating. The pre-patterning increases a surface roughness of the top surface of the semiconductor structure 100.

FIGS. 2B, 2C, and 2D illustrate the grain size gradient, crystallization ratio gradient, and crystal orientation consistency gradient inside the thermal dissipation layer 104, respectively. In each figure, the initial value of the grain size (GO), crystallization ratio (CO), and crystal orientation consistency (O0) of the thermal dissipation layer 104 prior to the transient heat treatment is also added as a reference. As shown in FIGS. 2B, 2C, and 2D, the transient heat treatment increases the grain size, crystallization ratio, and crystal orientation consistency inside the thermal dissipation layer 104, each of which contributes to an increased thermal conductivity. Further, each curve shows a gradient climbing up to the top surface of the thermal dissipation layer 104, such that a top portion of the thermal dissipation layer 104 has a higher grain size, crystallization ratio, and crystal orientation consistency than its bottom portion. This is due to the higher temperature received at the top portion of the thermal dissipation layer 104 than its bottom portion (as shown in FIG. 2A). The effectiveness of the transient heat treatment may be monitored by Raman spectroscopy and/or X-ray diffraction (XRD) spectroscopy.

Reference is now made to FIG. 1D. FIG. 1D illustrates the semiconductor structure 100 after the capping layer 106 is removed. Compared with FIG. 1A, the grain sizes in the thermal dissipation layer 104 as illustrated in FIG. 1D are enlarged due to the transient heat treatment. The capping layer 106 may be removed in an etching process, such as a wet etching process or a dry etching process. In one example, the removal of the capping layer 106 is performed using a process gas comprising fluorine and carbon. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm.

The formation flow of the thermal dissipation layer 104 as illustrated in FIGS. 1A-1D may be repeated to grow a second thermal dissipation layer or even more thermal dissipation layers stacked, such as to further grow a thickness of the overall thermal dissipation layer. One exemplary resulting structure is illustrated in FIG. 1E, in which a second thermal dissipation layer 104′ is formed. In each of the sub thermal dissipation layers, the gradients as illustrated in FIGS. 2B-2D repeats with a discontinuity at the interface between two adjacent sub thermal dissipation layers, which as explained above is mainly due to the temperature gradient during the transient heat treatment. Also, the interface between adjacent sub thermal dissipation layers is discernible.

In some embodiments, the thermal dissipation layer 104 as shown in FIG. 1D may be used as a seed layer for further growing a thicker thermal dissipation layer in a low-temperature deposition process that is below 400 degrees Celsius. One exemplary resulting structure is illustrated in FIG. 1F, in which a thicker thermal dissipation layer 104″ is formed. The low-temperature deposition process may be a PVD or a CVD process in some embodiments. One benefit in such a process is that the transit heat treatment needs to be performed only once during the formation of the seed layer 104, while the further growing of the thicker thermal dissipation layer 104″ does not require a further transit heat treatment. In one example, the seed layer 104 has a thickness between about 10 nm and about 300 nm, while the thicker thermal dissipation layer 104″ has a thickness larger than about 500 nm. Since the thicker thermal dissipation layer 104″ extends the lattice of the seed layer 104, it may also inherit and continue the grain size (G2 in FIG. 2B), crystallization ratio (C2 in FIG. 2C), and crystal orientation consistency (02 in FIG. 2D) at the top portion of the seed layer 104. Also, the interface between the seed layer 104 and the thicker thermal dissipation layer 104″ may be indiscernible.

FIG. 1G illustrates an embodiment of the semiconductor structure 100 having a dielectric or insulating layer 112 adjacent the thermal dissipation layer 104. In furtherance, the insulating layer 112 may surround the thermal dissipation layer 104, such that the thermal dissipation layer 104 is in the form of an island. The insulating layer 112 is for promoting bonding or sealing if the thermal conductive material selected for the thermal dissipation layer 104 is deemed insufficient for providing a strong bonding or sealing. The insulating layer 112 and the thermal dissipation layer 104 have different compositions. The insulating layers 112 may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials.

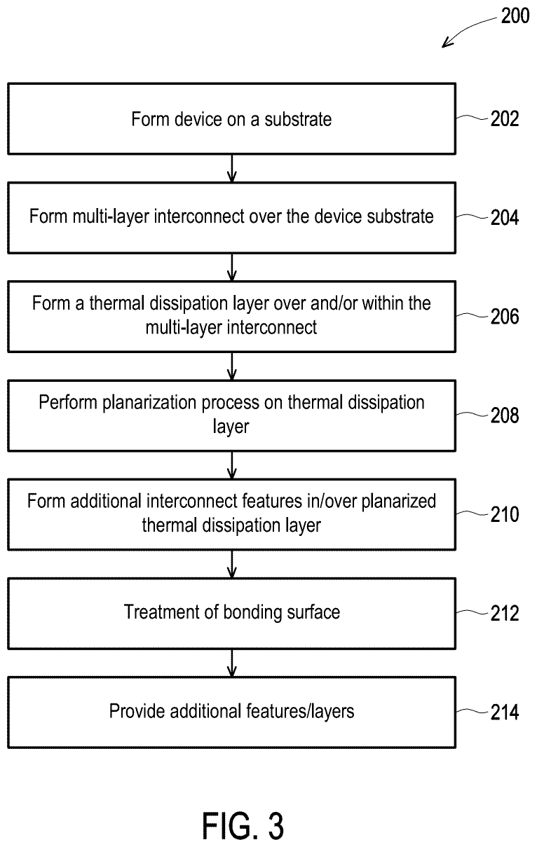

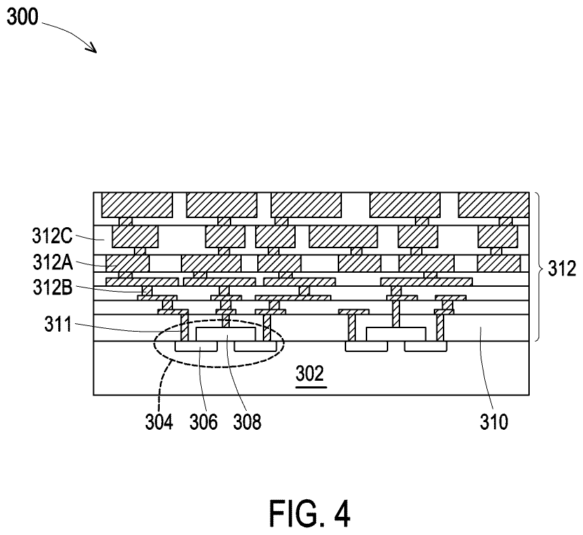

Referring now to FIG. 3, illustrated is a method 200 for forming a semiconductor structure 300 or portion thereof. In some embodiment, the fabrication of the semiconductor structure 300 may be substantially similar to the fabrication of the semiconductor structure 100 as discussed above with reference to FIGS. 1A-1G. The blocks of method 200 are exemplary only and additional steps may be performed and/or steps may be omitted. FIGS. 4-11 are illustrative of portions of an exemplary semiconductor structure corresponding to the interim fabrication steps of the method 200.

In an embodiment of the method 200, in a block 202, a semiconductor device such as a transistor is formed on a substrate. The device may be a portion of an IC. Referring to the example of FIG. 4, a substrate 302 is provided having one or more transistors 304 including source/drain regions 306 and gate structures 308 disposed thereon. As discussed above, the transistors 304 may be planar transistors or multi-gate transistors. The substrate may be substantially similar to as discussed above. For example, in an embodiment the semiconductor substrate 302 includes silicon (Si). Alternatively or additionally, substrate 302 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 302 includes one or more group III-V materials, one or more group II-IV materials, or combinations thereof. In some implementations, the substrate 302 is a semiconductor-on-insulator substrate, such as a silicon-on-insulator (SOI) substrate, a silicon germanium-on-insulator (SGOI) substrate, or a germanium-on-insulator (GeOI) substrate.

The source/drain regions 306 may be doped regions and/or epitaxially grown regions defining the source/drain feature associated with a gate structure 308 of the semiconductor device. The source/drain regions 306 may be deposited using vapor-phase epitaxy (VPE), ultra-high vacuum CVD (UHV-CVD), molecular beam epitaxy (MBE), and/or other suitable processes. When source/drain region 306 is n-type, it may include silicon (Si) doped with an n-type dopant, such as phosphorus (P) or arsenic (As). When a source/drain region 306 is p-type, it may include silicon germanium (SiGe) doped with a p-type dopant, such as boron (B) or boron difluoride (BF₂). In some embodiments, the source/drain regions 306 may include multiple layers such as layers with different dopant concentrations.

The gate structure 308 includes an interfacial layer, a gate dielectric layer, and a gate electrode. The interfacial layer of the gate structures 308 may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may be formed on the interfacial layer. The gate dielectric layer may include a high-k dielectric material, such as hafnium oxide. Alternatively, the gate dielectric layer of the gate structures 308 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods. The gate electrode layer of the gate structures 308 may include a single layer or alternatively a multi-layer structure, such as various combinations of a metal layer with a selected work function to enhance the device performance (work function metal layer), a liner layer, a wetting layer, an adhesion layer, a metal alloy, or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

A dielectric layer 310, also referred to as an inter-layer dielectric (ILD) layer, may be formed on the substrate 302 and adjacent the gate structures 308. The ILD layer 310 may be deposited using PECVD, FCVD, spin-on coating, or a suitable deposition technique. In some embodiments, after formation of the ILD layer 310, the structure may be annealed to improve integrity of the ILD layer 310. Although not explicitly shown in figures it is understood a contact etch stop layer (CESL) may be deposited before the ILD layer 310 is deposited such that the CESL is disposed between the ILD layer 310 and the source/drain features. The CESL may include silicon nitride or silicon oxynitride and may be deposited using CVD, ALD, or a suitable method.

Contact structures 311 extend through the ILD layer 310 to the source/drain regions 306 and the gate structure 308. The contact structures 311 may be referred to as middle-end-of-the-line (MEOL) structures. The contact structures 311 may include ruthenium (Ru), cobalt (Co), nickel (Ni), tungsten (W), copper (Cu), or other metals, as examples. In some embodiments, the contact structures 311 may include a barrier layer to interface the ILD layer 310. Such a barrier layer may include a metal nitride, such as titanium nitride, tantalum nitride, tungsten nitride, cobalt nitride, or nickel nitride. Additionally, in order to reduce contact resistance, a silicide feature may be a portion of the contact structures 311 and interface the transistor feature such as gate structure 308. The silicide feature may include titanium silicide. The contact structures 311 may be deposited using CVD, PVD, or a suitable method.

The method 200 then proceeds to block 204 where a multi-layer interconnect (MLI) is formed over the device. Referring to the example of FIG. 4, an MLI 312 is provided with metal layers that include metal lines 312A and vias 312B formed over the substrate 302. While six (6) metal layers are shown for ease of reference, any number of metal layers may be provided. Dielectric layer 312C interposes the metal lines 312A and vias 312B. The metal lines 312A and vias 312B may include copper (Cu). Other compositions include those discussed above titanium (Ti), ruthenium (Ru), nickel (Ni), cobalt (Co), copper (Cu), molybdenum (Mo), tungsten (W), aluminum (Al), or combinations thereof. The dielectric layer 312C may be deposited using PECVD, FCVD, spin-on coating, or a suitable deposition technique. The dielectric layer 312C may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the dielectric layer 312C includes silicon oxide. Each of the MLI 312 features may include a multi-layer structure. As discussed in embodiments below, one or more of the layers of the dielectric layer 312C may include a thermal conductive material composition. In some embodiments, at least a first dielectric layer 312C is an oxide-based layer (e.g., adjacent the ILD 310) and at least one dielectric layer 312C above the first dielectric layer 312C (e.g., in M4 or above) is a thermal conductive material composition.

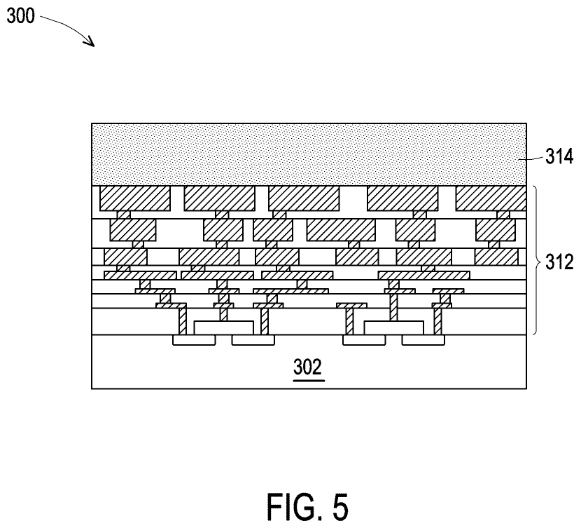

The method 200 then proceeds to block 206 where a thermal dissipation layer is formed over and/or within the multi-layer interconnect. Referring to the example of FIG. 5, a thermal dissipation layer 314 is formed over the MLI 312. The thermal dissipation layer 314 may be substantially similar to the thermal dissipation layer 104 discussed above with reference to FIGS. 1A-1G. In some embodiments, the thermal dissipation layer 314 is a single layer structure, such as shown in FIG. 1D. In some embodiments, the thermal dissipation layer 314 includes two or more sub layers, such as shown in FIG. 1E. In some embodiments, the thermal dissipation layer 314 includes a thinner seed layer and a thicker thermal dissipation layer, such as shown in FIG. 1F. In some embodiments, the thermal dissipation layer 314 includes thermal conductive material in the form of islands surrounded by other dielectric layer, such as shown in FIG. 1G. The thermal dissipation layer 314 may have a thickness of between approximately 0.5 microns (μm) and 10 μm. The thermal dissipation layer may be initially deposited at a temperature less than or equal to approximately 400 degrees Celsius, and subsequently activated in a transient heat treatment. Exemplary deposition methods include CVD, PVD, or ALD. A sacrificial capping layer substantially similar to the capping layer 106 as shown in FIGS. 1B and 1C may be optionally deposited on the thermal dissipation layer 314 prior to the transient thermal treatment and subsequently removed after the transient thermal treatment. In some embodiments, the transient thermal treatment may increase the thermal conductivity of the thermal dissipation layer 314 three to ten folds.

In an embodiment, the method 200 proceeds to block 208 where a planarization is performed on the thermal dissipation layer 314. In some implementations, the planarization may include a chemical mechanical planarization (CMP) process or ion milling. In an embodiment, the surface of the thermal dissipation layer 314 has a roughness root mean square (RMS) of between 5 nm and 100 nm before the planarization process or ion milling process and an RMS of less than approximately 1 nm after planarization.

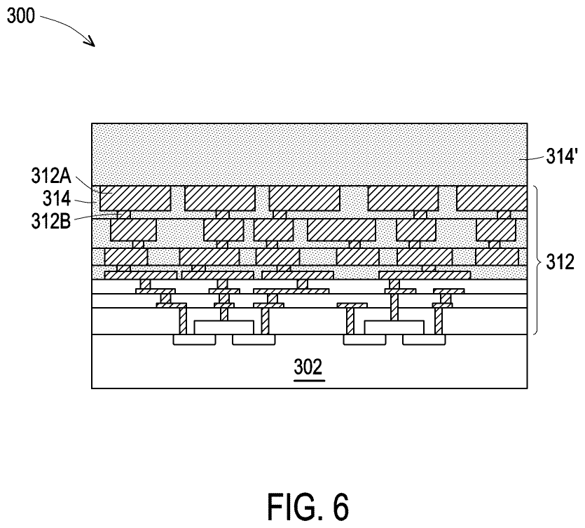

In other examples the material suitable for the thermal dissipation layer 314 (e.g., boron nitride or diamond-like carbon) may also be used as one or more IMD layers 312C within the MLI 312, such as shown in FIG. 6. In some implementations, the dielectric layer corresponding with metal layer four (M4) and above include the thermal dissipation layer 314 as the inter-metal dielectric. That is, the lower dielectric layers IMD layers 312C of the MLI 312 may include different dielectric materials than the upper dielectric layers 312C of the MLI 312. In an embodiment, the upper dielectric layers 312C of the MLI 312 includes thermal conductive material, such as boron nitride or diamond-like carbon, while the lower dielectric layers 312C of the MLI 312 include one or more of silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In other embodiments, each of the IMD layers of the MLI 312 comprises the thermal conductive material (e.g., boron nitride or diamond-like carbon). As illustrated in FIG. 6, the metal lines 312A and vias 312B are formed within the thermal dissipation layer 314. As illustrated in the semiconductor structure 300 of FIG. 6, in some implementations over the MLI 312 another thermal dissipation layer 314′ is formed. This upper thermal dissipation layer 314′ may be thicker than those provided within the MLI 312.

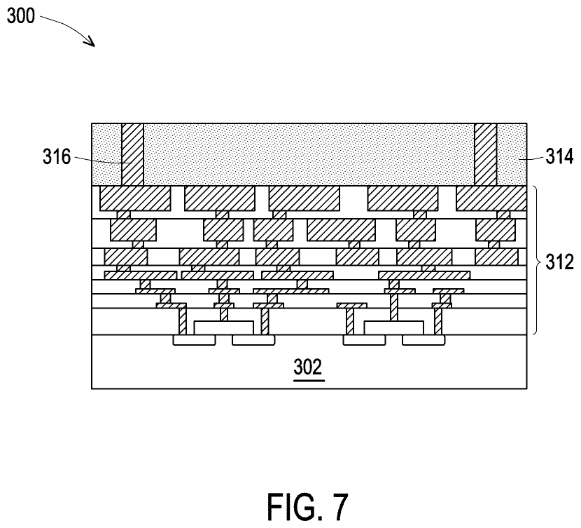

In an embodiment of the method 200, the method proceeds to block 210 where an additional interconnect features are formed in the thermal dissipation layer 314. Referring to FIG. 7, vias 316 are formed extending through the thermal dissipation layer 314. The vias 316 interface an uppermost metallization (e.g., metal line 312A) of the MLI 312 to provide an electrical connection. The vias 316 may be formed by suitable photolithography and etching processes to form openings in the thermal dissipation layer 314, followed by deposition of one of more conductive materials into the opening to form the vias 316. Example compositions include copper (Cu), titanium (Ti), ruthenium (Ru), nickel (Ni), cobalt (Co), copper (Cu), molybdenum (Mo), tungsten (W), aluminum (Al), tantalum (Ta) or combinations thereof.

In some implementations, the method 200 continues to block 212 to treat the surface of the thermal dissipation layer 314. The treatment may include preparing the surface for bonding with additional layers or features. In some implementations, a surface treatment or activation process is performed on the thermal dissipation layer 314 such as a cleaning process and/or a plasma treatment. In some implementations, block 212 is omitted.

In some implementations, the method 200 continues to block 214 where additional layers or features are formed on the structure. The additional layers or features may include other semiconductor structures such as other die(s), heat sinks, package features such as input/output terminals (e.g., balls, bumps, pillars), substrates such as semiconductor substrates or interposer substrates, carrier substrates, and/or various other features including those implementing 3D IC structures.

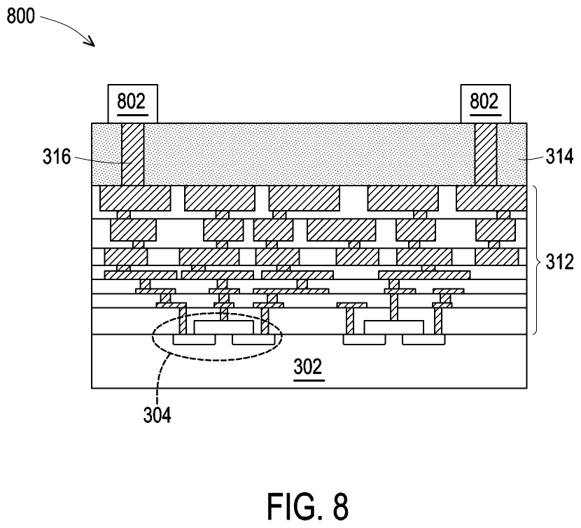

Referring now to FIGS. 8-11, illustrated are semiconductor structures that may be formed using one or more aspects at block 214 of the method 200. Any aspect of any one of the exemplary devices may be used in conjunction with the other embodiments.

Referring to the example of FIG. 8, a semiconductor structure 800 is illustrated that includes a semiconductor substrate 302, semiconductor devices 304, MLI 312, and a thermal dissipation layer 314, which may be substantially similar to as discussed above. The semiconductor structure 800 may be fabricated using aspects of the method 200 discussed above. As illustrated in the semiconductor structure 800, conductive features 802 are provided over the thermal dissipation layer 314 and connected to the vias 316. The conductive features 802 may be interconnects such as C4 bump interconnects, pillars (e.g., copper pillars), C3 balls, solder balls, and/or other conductive features. In some implementations, the conductive features are connected to another semiconductor structure such as another die, an interposer substrate, operable for connection to a printed circuit board and/or other packaging structures. Passivation or underfill materials (not shown) may be formed over the thermal dissipation layer 314 and adjacent the conductive features 802.

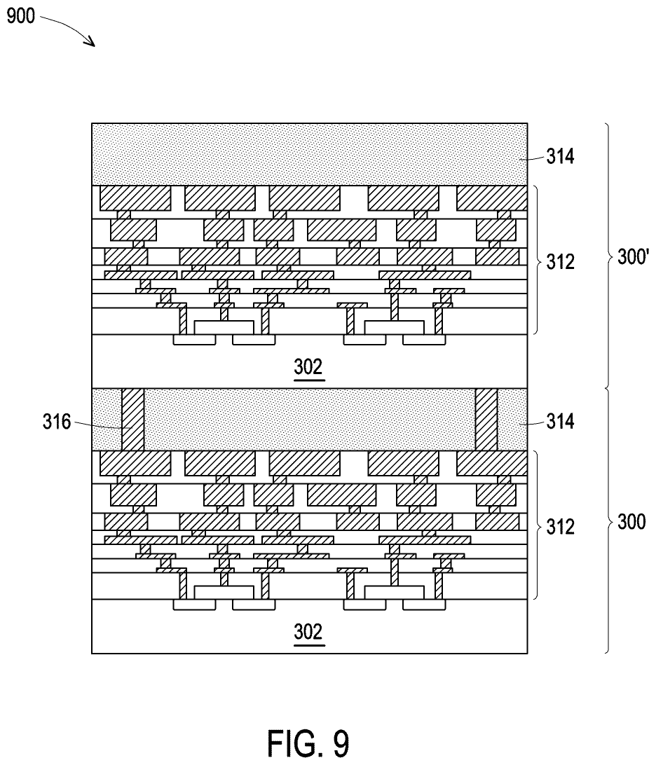

Referring to the example of FIG. 9, a semiconductor structure 900 is shown having a second die 300′ provided over the thermal dissipation layer 314 of the semiconductor structure 300. The semiconductor structure 300 may be substantially similar to as discussed above with reference to the method 200 and FIGS. 5-7. In an embodiment, the second die 300′ may be substantially similar to the first semiconductor structure 300. In some implementations, the first semiconductor structure 300 and the second die 300′ may comprise a different IC. The thermal dissipation layer 314 also serves as a bonding layer. The vias 316 provide electrical connection for signals and/or powers between the semiconductor structure 300 and the second die 300′.

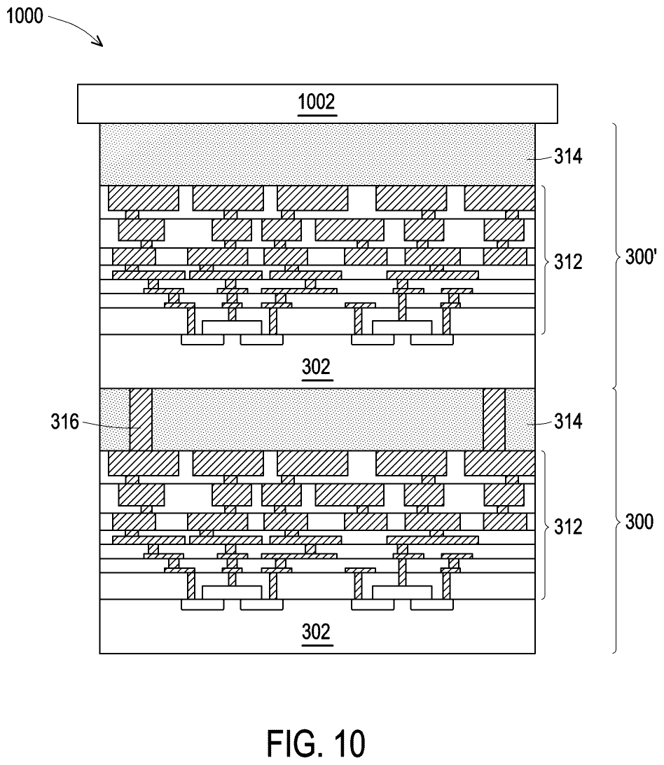

Referring to the example of FIG. 10, a semiconductor structure 1000 is shown having a second die 300′ provided over the thermal dissipation layer 314 of the semiconductor structure 300. The semiconductor structure 300 may be substantially similar to as discussed above with reference to the method 200 and FIGS. 5-7. In an embodiment, the second die 300′ may be substantially similar to the first semiconductor structure 300. In some implementations, the first semiconductor structure 300 and the second die 1102 may comprise a different IC. The thermal dissipation layer 314 also serves as a bonding layer. The vias 316 provide electrical connection for signals and/or powers between the semiconductor structure 300 and the second die 300′. Over the second die 300′ including its thermal dissipation layer 314 is an additional component 1002. In an embodiment, the additional component 1002 is another die such as another die substantially similar to the semiconductor structure 300 and/or the die 300′. In an embodiment, the additional component 1002 is another IC device including a die having a different functionality and/or footprint than the semiconductor structure 300 and/or the die 300′. In an embodiment, the additional component 1002 is a carrier substrate such as a glass substrate. In an embodiment, the additional component 1002 is another substrate. In some embodiments, the component 1002 includes a silicon (Si) substrate. Alternatively or additionally, component 1002 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the component 1002 is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods. In an embodiment, the component 1002 is a heatsink. The heatsink may include a thermally conductive plate (e.g., copper or aluminum), coolant in piping, and/or other configurations.

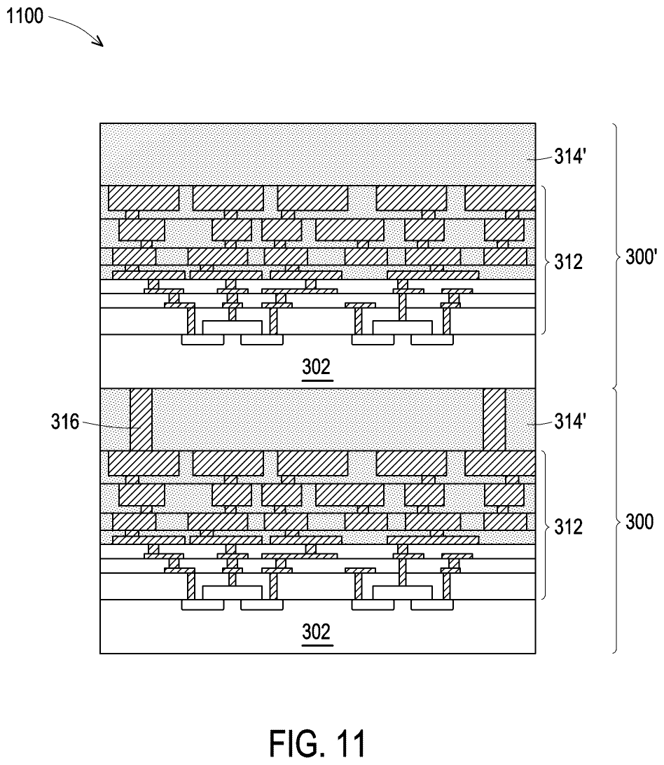

Referring to the example of FIG. 11, a semiconductor structure 1100 is shown having a second die 300′ provided over the thermal dissipation layer 314 of the semiconductor structure 300. The semiconductor structure 300 may be substantially similar to as discussed above with reference to the method 200 and FIGS. 5-7. Particularly, in the illustrated embodiment, the first semiconductor structure 300 includes upper dielectric layers of the MLI 312 comprised of a thermal conductive material, such as shown in FIG. 6. In an embodiment, the second die 300′ may be substantially similar to the first semiconductor structure 300. In an embodiment, the second die 300′ may be substantially similar to the first semiconductor structure 300. In some implementations, the first semiconductor structure 300 and the second die 300′ may comprise a different IC. The thermal dissipation layer 314′ also serves as a bonding layer. The vias 316 provide electrical connection for signals and/or powers between the semiconductor structure 300 and the second die 300′.

Thus, provided are structures and methods that allow for stacking features such as in a 3D IC configuration having a thermal dissipation layer within the stack. Although not limiting, the present disclosure offers advantages for IC semiconductor structures with thermal dissipation layers compatible with low-temperature BEOL processes. In furtherance, the proposed thermal dissipation layer may also serve as a bonding layer.

One aspect of the present disclosure pertains to a method of semiconductor device fabrication. The method includes forming a transistor on a semiconductor substrate, forming a first metal layer and an overlying second metal layer over the transistor, depositing a thermal dissipation layer over the overlying second metal layer, and annealing the thermal dissipation layer to a temperature above the threshold temperature. The depositing of the thermal dissipation layer is performed below a threshold temperature. During the annealing, the first metal layer and the overlying second metal layer are maintained below the threshold temperature. In some embodiments, the annealing includes a transient heat treatment. In some embodiments, the annealing includes applying a pulsed laser to locally heat up the thermal dissipation layer. In some embodiments, the threshold temperature is about 400 degrees Celsius. In some embodiments, the annealing increases a thermal conductivity of the thermal dissipation layer. In some embodiments, the method further includes prior to the annealing, depositing a capping layer over the thermal dissipation layer, and after the annealing, removing the capping layer. In some embodiments, the capping layer includes at least one of Ti, Al, Ni, silicon glass, Cr, Al₂O₃, SiO₂, carbon, or a metal. In some embodiments, the thermal dissipation layer includes at least one of boron nitride, aluminum nitride, graphene, carbon, diamond, diamond-like carbon, benzoic acid, or transition metal dichalcogenide. In some embodiments, the method further includes forming a via extending through the thermal dissipation layer. In some embodiments, the method further includes stacking a die above the thermal dissipation layer. The via provides electrical coupling between the transistor and the die.

Another aspect of the present disclosure pertains to a method. The method includes forming a transistor device on a substrate, forming a multi-layer interconnect (MLI) over the transistor device, depositing a thermal conductive material on the MLI, after the depositing of the thermal conductive material, performing a thermal treatment to the thermal conductive material to increase a thermal conductivity of the thermal conductive material, and planarizing the thermal conductive material. In some embodiments, the thermal treatment includes applying a pulsed laser. In some embodiments, during the thermal treatment, a temperature inside the MLI is maintained below about 400 degrees Celsius. In some embodiments, the thermal treatment enlarges a grain size of the thermal conductive material. In some embodiments, the thermal treatment converts the thermal conductive material form an amorphous state to a crystalline state. In some embodiments, the thermal treatment increases a crystal orientation consistency inside the thermal conductive material. In some embodiments, the method further includes prior to the thermal treatment, depositing a capping layer over the thermal conductive material, and after the thermal treatment, removing the capping layer.

Another aspect of the present disclosure pertains to a method of forming an integrated circuit (IC) structure. The IC structure includes a transistor device formed on a substrate, the transistor device having source/drain (S/D) regions and a gate structure, a multi-layer interconnect (MLI) structure over the transistor device, the MLI structure including metal lines and metal vias embedded in an intermetal dielectric (IMD) layer, and a thermal dissipation layer disposed over at least a portion of the MLI structure. A top portion of the thermal dissipation layer has a grain size larger than a bottom portion of the thermal dissipation layer. In some embodiments, the thermal dissipation layer includes through-vias electrically coupled to the MLI structure. In some embodiments, the IC structure further includes a die bonded to the thermal dissipation layer. The through-vias provide electrical connection between the MLI structure and the die.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of transistors in a semiconductor substrate;
forming a multi-layer interconnect structure over the semiconductor substrate, the multi-layer interconnect structure comprising a plurality of interconnect layers, each of the interconnect layers comprising metal lines disposed in a dielectric layer, a thickness of a dielectric layer in a bottommost one of the interconnect layers being less than a thickness of a dielectric layer in at least one of the interconnect layers above the bottommost one of the interconnect layers;
depositing a thermal dissipation layer over the multi-layer interconnect structure;
depositing a light absorption layer over the thermal dissipation layer;
annealing the thermal dissipation layer with a pulsed light to increase a thermal conductivity of the thermal dissipation layer, the light absorption layer increasing a light absorption rate of the thermal dissipation layer during the annealing; and
after the annealing, removing the light absorption layer.

2. The method of claim 1, wherein the pulsed light is a pulsed laser.

3. The method of claim 1, wherein the pulsed light is scanned line by line in parallel on the light absorption layer with overlapping between adjacent lines during the annealing.

4. The method of claim 1, wherein the depositing of the thermal dissipation layer is performed below a threshold temperature, the annealing increased a temperature in the thermal dissipation layer above the threshold temperature, and during the annealing a temperature in a topmost one of the interconnect layers of the multi-layer interconnect structure is maintained below the threshold temperature.

5. The method of claim 4, wherein the threshold temperature is about 400 degrees Celsius.

6. The method of claim 1, wherein prior to the annealing the thermal conductivity of the thermal dissipation layer is less than 10 W/m-K, and after the annealing the thermal conductivity of the thermal dissipation layer is greater than 10 W/m-K.

7. The method of claim 1, wherein the thermal dissipation layer is a first thermal dissipation layer and the light absorption layer is a first light absorption layer, the method further comprising:
after the removing of the first light absorption layer, depositing a second thermal dissipation layer;
depositing a second light absorption layer over the second thermal dissipation layer;
annealing the second thermal dissipation layer; and
removing the second light absorption layer.

8. The method of claim 1, further comprising:
forming a plurality of vias extending through the thermal dissipation layer.

9. The method of claim 8, further comprising:
stacking a die above the thermal dissipation layer, wherein the vias provide electrical coupling between the transistors and the die.

10. A method, comprising:
forming a plurality of transistors in a semiconductor substrate;
forming a multi-layer interconnect structure over the semiconductor substrate, the multi-layer interconnect structure comprising a plurality of interconnect layers, each of the interconnect layers comprising metal lines disposed in a dielectric layer, a thickness of a metal line in a bottommost one of the interconnect layers being less than a thickness of a metal line in at least one of the interconnect layers above the bottommost one of the interconnect layers;
depositing a thermal conductive material on the multi-layer interconnect structure;
after the depositing of the thermal conductive material, performing a thermal treatment to the thermal conductive material to increase a thermal conductivity of the thermal conductive material; and
planarizing the thermal conductive material.

11. The method of claim 10, wherein the thermal treatment converts the thermal conductive material form an amorphous state to a crystalline state.

12. The method of claim 11, wherein the thermal conductivity material is boron nitride.

13. The method of claim 10, wherein during the thermal treatment, a temperature inside the multi-layer interconnect structure is maintained below about 400 degrees Celsius.

14. The method of claim 10, wherein the thermal treatment enlarges a grain size of the thermal conductive material.

15. The method of claim 11, wherein the thermal treatment increases a crystal orientation consistency inside the thermal conductive material.

16. The method of claim 10, wherein the thermal treatment includes applying a pulsed laser, the method further comprising:
prior to the thermal treatment, depositing a light absorption layer over the thermal conductive material; and
after the thermal treatment, removing the light absorption layer.

17. A semiconductor structure, comprising:
a substrate having a plurality of transistors formed therein, the transistors comprising source/drain regions and gate structures, the gate structures comprising a gate dielectric layer and a gate electrode over the gate dielectric layer, the gate electrode comprising a titanium-containing material;
a multi-layer interconnect (MLI) structure over the substrate, the MLI structure comprising a plurality of intermetal dielectric (IMD) layers, each of the IMD layers comprising a plurality of metal lines and a plurality of metal vias; and
a thermal dissipation layer disposed over at least a portion of the MLI structure, wherein a top portion of the thermal dissipation layer has a grain size larger than a bottom portion of the thermal dissipation layer.

18. The semiconductor structure of claim 17, wherein the top portion of the thermal dissipation layer has a crystal orientation consistency higher than the bottom portion of the thermal dissipation layer.

19. The semiconductor structure of claim 17, wherein the thermal dissipation layer includes a plurality of through-vias electrically coupled to the MLI structure.

20. The semiconductor structure of claim 19, further comprising:
a die bonded to the thermal dissipation layer, wherein the through-vias provide electrical connection between the MLI structure and the die.
